(19) United States
(12) Patent Application Publication
(10) Pub. No.: US 2025/0275378 A1
(43) Pub. Date: Aug. 28, 2025

(54) ELECTRO-OPTICAL DEVICE AND ELECTRONIC APPARATUS

(71) Applicant: SEIKO EPSON CORPORATION, Tokyo (JP)

(72) Inventor: Yuiga HAMADE, Matsumoto-shi (JP)

(73) Assignee: SEIKO EPSON CORPORATION, Tokyo (JP)

(21) Appl. No.: 19/062,514

(22) Filed: Feb. 25, 2025

(30) Foreign Application Priority Data
Feb. 26, 2024 (JP) 2024-026354

(51) Int. Cl. H10K 59/122

(52) U.S. Cl. CPC H10K 59/122

(57) ABSTRACT

An electro-optical device includes a substrate, a pixel electrode, a light-emitting layer in contact with the pixel electrode in plan view at an opening region defined by an opening end, a common electrode that sandwiches the light-emitting layer with the pixel electrode, a conductive partition wall being in contact with the common electrode and surrounds the pixel electrode, the light-emitting layer, and the common electrode in plan view, and an upper portion provided on the upper surface of the partition wall to protrude from the partition wall in cross-sectional view. When a distance of a Z-direction component of a straight line coupling a tip of the upper portion to the opening end is defined as α and a distance of a component of the straight line along a substrate surface is defined as β, there is a relationship of α>β.

The present application is based on, and claims priority from JP Application Serial Number 2024-026354, filed Feb. 26, 2024, the disclosure of which is hereby incorporated by reference herein in its entirety.

### BACKGROUND

### 1. Technical Field

The present disclosure relates to an electro-optical device and an electronic apparatus.

### 2. Related Art

An electro-optical device using, for example, an OLED as a display element is known. The OLED is an abbreviation for Organic Light Emitting Diode. Such a light-emitting element has a configuration in which a light-emitting layer is sandwiched between a pixel electrode and a common electrode. Since the common electrode is common to all pixel portions, it is necessary to curb voltage unevenness due to resistance components. Therefore, a technology for surrounding the pixel electrode, the light-emitting layer, and the common electrode in plan view with a conductive partition wall and applying a voltage to the common electrode via the conductive partition wall is known.

### CITATION LIST

### Patent Literature

[PTL 1] JP-A-2023-100414

However, when an interval between pixel portions is narrowed to a few μm, there is a problem that light emitted from the light-emitting layer is shielded by an upper portion provided on an upper surface of the partition wall, or an aperture ratio in the pixel portion is reduced.

### SUMMARY

An advantage of some aspects of the disclosure provides an electro-optical device including a substrate, a first electrode, a second electrode provided between the substrate and the first electrode, a pixel separation layer having an insulative property, and covering the periphery of the second electrode and opening in an opening region overlapping the second electrode in plan view, a light-emitting layer provided between the first electrode and the second electrode and being in contact with the second electrode in the opening, a partition wall having a light-shielding property against light emitted by the light-emitting layer and surrounding the first electrode, the light-emitting layer, and the second electrode in plan view, and an upper portion provided so as to protrude from the partition wall in cross-sectional view on an upper surface of the partition wall, and having a light-shielding property against light emitted by the light-emitting layer, wherein, when a distance of a normal component to the substrate of a shortest straight line coupling a tip of the upper portion to an opening end of the opening region in cross-sectional view is defined as a, and a distance of a component of the straight line along a surface of the substrate is defined as, there is a relationship of α>β.

### BRIEF DESCRIPTION OF THE DRAWINGS

FIG. 1 is a perspective view illustrating a configuration of an electro-optical device according to a first embodiment.

FIG. 2 is a diagram illustrating an electrical configuration of the electro-optical device.

FIG. 3 is a diagram illustrating a configuration of a pixel circuit in the electro-optical device.

FIG. 4 is a diagram illustrating an operation of the electro-optical device.

FIG. 5 is a plan view illustrating main portions of a pixel portion in the electro-optical device.

FIG. 6 is a partial cross-sectional view schematically illustrating the electro-optical device.

FIG. 7 is a partial cross-sectional view illustrating the electro-optical device.

FIG. 8 is a partial cross-sectional view illustrating the electro-optical device.

FIG. 9 is a partial enlarged cross-sectional view illustrating the electro-optical device.

FIG. 10 is a diagram illustrating a relationship between an observation angle and a relative luminance in the electro-optical device.

FIG. 11 is a partially enlarged cross-sectional view illustrating the electro-optical device.

FIG. 12 is a partially enlarged cross-sectional view illustrating an electro-optical device according to a first embodiment.

FIG. 13 is a partially enlarged cross-sectional view illustrating an electro-optical device according to a second embodiment.

FIG. 14 is a partially enlarged cross-sectional view illustrating an electro-optical device according to a third embodiment.

FIG. 15 is a partially enlarged cross-sectional view illustrating an electro-optical device according to a comparative example.

FIG. 16 is a partially enlarged cross-sectional view illustrating an electro-optical device according to a first application example.

FIG. 17 is a partially enlarged cross-sectional view illustrating an electro-optical device according to a second application example.

FIG. 18 is a perspective view illustrating a head-mounted display using the electro-optical device.

FIG. 19 is a diagram illustrating an optical configuration of the head-mounted display.

### DESCRIPTION OF EMBODIMENTS

Hereinafter, an electro-optical device according to an embodiment will be described with reference to the accompanying drawings. In each drawing, dimensions and scales of each portion are appropriately different from actual ones. Further, since embodiments to be described below are preferred specific examples, various technically preferable limitations are applied, but the scope of the present disclosure is not limited to these embodiments unless it is otherwise stated in the following description that the present disclosure is limited.

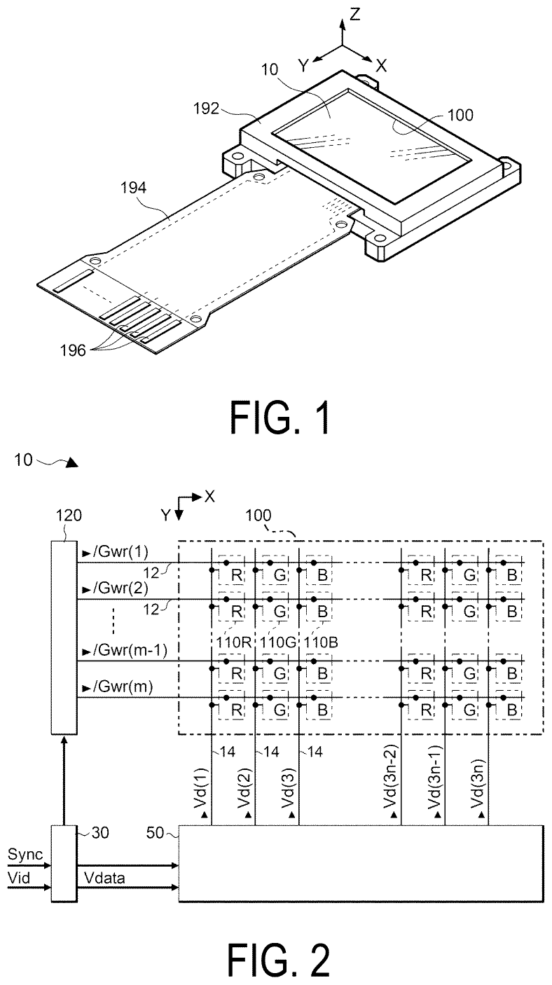

FIG. 1 is a perspective view illustrating an electro-optical device 10 according to a first embodiment, and FIG. 2 is a block diagram illustrating an electrical configuration of the electro-optical device 10.

The electro-optical device 10 is a micro display panel that displays color images, for example, in a head-mounted display. The electro-optical device 10 includes a plurality of pixel portions or a driving circuit that drives the pixel portions. The pixel portions and the driving circuit are integrated on a semiconductor substrate. The semiconductor substrate is typically a silicon substrate, but may be another semiconductor substrate.

The electro-optical device 10 is accommodated in a frame-shaped case 192 that opens in the display region 100. One end of an FPC board 194 is coupled to the electro-optical device 10. FPC is an abbreviation for Flexible Printed Circuit. The other end of the FPC board 194 is provided with a number of terminals 196 for coupling to a host device ((not illustrated)). When a plurality of terminals 196 are coupled to the host device, video data, a synchronization signal, and the like are supplied from the host device to the electro-optical device 10 via the FPC board 194.

As illustrated in FIG. 2, the electro-optical device 10 is broadly divided into a control circuit 30, a data signal output circuit 50, a display region 100, and a scanning line driving circuit 120.

In the display region 100, m rows of scanning lines 12 are provided along an X direction, and (3n) columns of data lines 14 are provided along a Y direction to be electrically insulated from each of the scanning lines 12. m is an integer equal to or greater than 2, and n is an integer equal to or greater than 2.

To generalize and explain the scanning lines 12, an integer i of 1 or more and m or less is used. To distinguish rows of the scanning lines 12, the rows may be referred to as first, second, third, . . . , i-th, . . . , (m−1)-th, m-th row from the top in the figure.

Similarly, an integer j of 1 or more and n or less is used to generalize and explain the data lines 14. To distinguish columns of the data lines 14, the columns may be referred to as first, second, third, . . . , (3j−2)-th, (3j−1)-th, (3j)-th, . . . , (3n−2)-th, (3n−1)-th, and (3n)-th columns from the left in the figure.

In the display region 100, a pixel portion 110R that emits light in a red wavelength region, a pixel portion 110G that emits light in a green wavelength region, and a pixel portion 110B that emits light in a blue wavelength region are provided in the following manner to correspond to intersections of the m-th row of scanning line 12 and the (3n)-th column of data line 14.

The pixel portion 110R is provided to correspond to an intersection of the scanning line 12 of each row and the (3j-2)-th column of data line 14. The pixel portion 110G is provided to correspond to an intersection of the scanning line 12 of each row and the (3j-1)-th column of data line 14. The pixel portion 110B is arranged to correspond to an intersection of the scanning line 12 of each row and the (3j)-th column of data line 14.

That is, in the display region 100, pixel portions 110R, 110G, and 110B are arranged in this order along the X direction. A single color is expressed by additive color mixing of three pixel portions 110R, 110G, and 110B adjacent in the X direction. Thus, the electro-optical device 10 displays an image in which color pixels are arranged in m rows and n columns.

Strictly speaking, the pixel portions 110R, 110G, and 110B should be called sub-pixel portions, but are referred to as pixel portions for convenience of description. Further, when the pixel portions 110R, 110G, and 110B are generally described without specifying the color, the pixel portions 110R, 110G, and 110B are denoted by a reference number 110.

The control circuit 30 controls each part based on the video data Vid or the synchronization signal Sync supplied from a host device (not illustrated). Specifically, the control circuit 30 generates various control signals to control the respective parts.

The video data Vid designates the gradation level of the pixel in the image to be displayed, for example, in 8 bits. The synchronization signal Sync includes a vertical synchronization signal for giving an instruction for starting vertical scanning of the video data Vid, a horizontal synchronization signal for giving an instruction for starting horizontal scanning, and a dot clock signal that indicates a timing of one pixel of the video data.

The luminance characteristics at the gradation level indicated by the video data Vid supplied from the host device do not necessarily match the luminance characteristics of the OLED included in the pixel portion 110. Thus, to make the OLED emit light at a luminance corresponding to the gradation level indicated by the video data Vid, the control circuit 30 up-converts 8 bits of the video data Vid into, for example, 10 bits and outputs it as video data Vdata. Therefore, the 10-bit video data Vdata becomes data corresponding to R, G, and B gradation levels designated by the video data Vid.

For the upconversion, a lookup table in which a correspondence relationship between 8 bits of the video data Vid that is an input and 10 bits of the video data Vdata that is an output is prestored is used.

The scanning line driving circuit 120 is a circuit for driving the pixel portions 110 arranged in m rows and 3n columns one by one under the control of the control circuit 30. For example, the scanning line driving circuit 120 supplies scanning signals /Gwr(1), /Gwr(2), . . . , /Gwr(m−1), /Gwr(m) to the scanning lines 12 in the first, second, third, . . . , (m−1)-th, and m-th rows in order. In general, the scanning signal supplied to the scanning line 12 in the i-th row is represented as/Gwr(i).

The data signal output circuit 50 is a circuit for outputting a data signal to the pixel portions 110 located in the row selected by the scanning line driving circuit 120 via the data line 14 under the control of the control circuit 30. The data signal is a voltage signal obtained by converting 10-bit video data Vdata into analog data. That is, the data signal output circuit 50 converts video data Vdata for one row corresponding to pixel portions 110 in the first to (3n)-th columns in the selected row into analog data, and outputs the analog data to the first to (3n)-th column of data lines 14 in this order.

Although not illustrated in the figure, a power supply circuit is provided outside the display region 100, and generates potentials Vel and Vct of a power supply for the control circuit 30, the scanning line driving circuit 120, the data signal output circuit 50, and the OLED.

In the figure, the data signals output to the first, second, third, . . . , (3n−2)-th, (3n−1)-th, and (3n)-th column of data lines 14 are denoted in order by Vd(1), Vd(2), Vd(3), . . . , Vd(3n−2), Vd(3n−1), and Vd(3n). Generally, for example, the potential of the data line 14 in the (3j−2)-th column is denoted by Vd(3j−2).

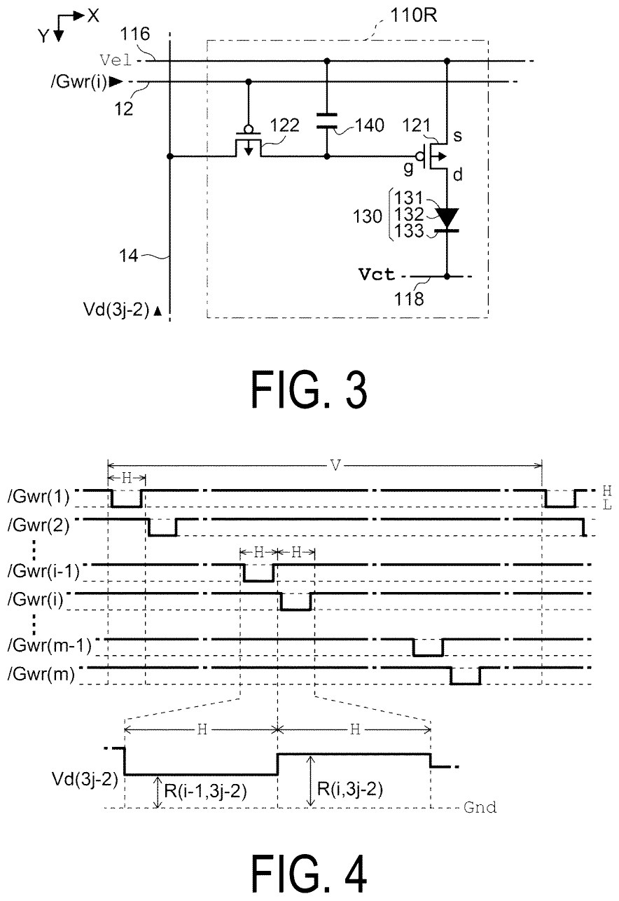

FIG. 3 is a diagram illustrating an electrical configuration of the pixel portion in the electro-optical device 10.

The pixel portions 110R, 110G, and 110B have the same configuration from an electrical perspective. Therefore, an electrical configuration of the pixel portions 110R, 110G, and 110B will be described with the pixel portion 110R corresponding to the i-th row and (3j−2)-th column as an example.

As shown in the figure, the pixel portion 110R includes P-channel MOS transistors 121 and 122, an OLED 130, and a capacitance element 140 from an electrical perspective.

In the description of the pixel portion, the term “from an electrical perspective” is used to refer to a plurality of elements constituting the pixel portion and a coupling relationship between the plurality of elements.

In the OLED 130 of the pixel portion 110R, a light-emitting layer 132R is sandwiched between a pixel electrode 131 and a common electrode 133. The light-emitting layer 132R emits light including an R wavelength range. The pixel electrode 131 functions as an anode, and the common electrode 133 functions as a cathode. In the OLED 130, when a current flows from the anode to the cathode, holes injected from the anode and electrons injected from the cathode are recombined in the light-emitting layer 132R to generate excitons, and light including the R wavelength range is generated.

In the OLED 130 of the pixel portion 110G, the light-emitting layer 132G is sandwiched between the pixel electrode 131 and the common electrode 133. The light-emitting layer 132G emits light including a G wavelength range. In the OLED 130 of the pixel portion 110B, the light-emitting layer 132B is sandwiched between the pixel electrode 131 and the common electrode 133. The light-emitting layer 132B emits light including a B wavelength range.

Each of the light-emitting layers 132R, 132G, and 132B includes at least a light-emitting functional layer that emits light of each color. The light-emitting layers 132R, 132G, and 132B may have a configuration in which one or more organic layers other than the light-emitting functional layer are sandwiched.

In the transistor 121 of the pixel portion 110R in the i-th row and the (3j−2)-th column, a gate node g is coupled to the drain node of the transistor 122, a source node is coupled to the power supply line 116 for the potential Vel, and a drain node is coupled to the pixel electrode 131 which is the anode of the OLED 130.

In the transistor 122 of the pixel portion 110R in the i-th row and the (3j−2)-th column, a gate node is coupled to the scanning line 12 in the i-th row, and a source node is coupled to the data line 14 of the (3j−2)-th column. The common electrode 133 functioning as the cathode of the OLED 130 is coupled to the power supply line 118 of a potential Vct. Further, since the electro-optical device 10 is formed at a silicon substrate, a substrate potential of the transistors 121 and 122 is set to, for example, a potential equivalent to the potential Vel.

The pixel portion 110R illustrated in FIG. 3 is common to the pixel portions 110G and 110B from an electrical perspective. However, the light-emitting layer 132R is replaced with the light-emitting layer 132G in the pixel portion 110G, and is replaced with the light-emitting layer 132B in the pixel portion 110B.

The X direction in FIGS. 1, 2, and 3 is a direction in which the scanning lines 12 extend in the electro-optical device 10, and indicates a horizontal direction on a display screen. The Y direction is a direction in which the data lines 14 extend and indicates a vertical direction on the display screen. A two-dimensional plane determined by the X direction and the Y direction is a substrate surface of the semiconductor substrate. A Z direction in FIG. 1 is perpendicular to the X direction and the Y direction, and is a direction in which light is emitted from the OLED 130. Further, in the present description, a plan view refers to viewing the semiconductor substrate from a direction opposite to the Z direction, and a cross-sectional view refers to viewing the semiconductor substrate cut in a direction perpendicular to the substrate surface.

FIG. 4 is a timing chart for describing an operation of the electro-optical device 10.

In the electro-optical device 10, the m rows of scanning lines 12 are scanned row by row in an order of first, second, third, . . . , m-th row in a period of a frame (V). Specifically, as shown in the figure, the scanning signals /Gwr(1), /Gwr(2), . . . , /Gwr(m−1), . . . , /Gwr(m) are sequentially and exclusively set to an L level by the scanning line driving circuit 120 for each horizontal scanning period (H).

In the present disclosure, periods in which adjacent scanning signals among scanning signals /Gwr(1) to /Gwr(m) become at an L level are separated in time. Specifically, after a scanning signal /Gwr(i−1) changes from an L level to a H level, the next scanning signal /Gwr(i) becomes at an L level after a period. This period corresponds to a horizontal blanking period.

In the present description, the period of the one frame (V) refers to a period required to display one frame of the image designated by the video data Vid. When a length of the period of the one frame (V) is the same as a vertical synchronization period, for example, when a frequency of the vertical synchronization signal included in the synchronization signal Sync is 60 Hz, the length is 16.7 milliseconds corresponding to one cycle of the vertical synchronization signal. Further, the horizontal scanning period (H) is a time interval in which the scanning signals /Gwr(1) to /Gwr(m) sequentially become at an L level, but for convenience in the figure, a start timing of the horizontal scanning period (H) is set as approximately a center of the horizontal blanking period.

When a certain scanning signal among the scanning signals /Gwr(1) to /Gwr(m), for example, the scanning signal /Gwr (i) supplied to the scanning line 12 in the i-th row becomes an L level, the transistor 122 enters an ON state in the pixel portion 110R of the i-th row and the (3j−2)-th column. As a result, the gate node g of the transistor 121 in the pixel portion 110R is electrically coupled to the data line 14 of the (3j−2)-th column.

In the present description, an “ON state” of the transistor means that the source node and drain node of the transistor are electrically closed and enters a low impedance state. Moreover, an “off state” of the transistor means that the source node and drain node are electrically open and enters a high impedance state.

Further, in the present description, “electrically coupled” or simply “coupled” means a state in which two or more elements are directly or indirectly coupled or connected. “Electrically decoupled” or simply “decoupled” means a state in which two or more elements are not directly or indirectly coupled or connected.

In the horizontal scanning period (H) in which the scanning signal /Gwr(i) becomes at the L level, the data signal output circuit 50 converts the video data Vdata decomposed into R, G, and B into analog potentials Vd(1) to Vd(3n) and outputs the analog potentials Vd(1) to Vd(3n) as data signals to the data lines 14 in the first to (3n)-th columns. The video data Vdata decomposed into R, G, and B is three primary color components of the gradation levels of the pixels in the first to i-th rows and the first to nth columns indicated by the video data Vid.

For example, in the case of the (3j−2)-th column, the data signal output circuit 50 converts the R gradation level R (i, j) of the pixel in the i-th row and the j-th column indicated by the video data Vid into an analog signal potential Vd(3j−2) and outputs the analog signal potential Vd(3j−2) as a data signal to the data line 14 in the (3j−2)-th column.

In the horizontal scanning period (H) when the scanning signal /Gwr(i−1) one row before the scanning signal /Gwr (i) becomes at the L level, the data signal output circuit 50 converts an R gradation level R (i−1, j) of the pixel in a (i−1)-th row and a j-th column into an analog signal potential Vd(3j−2) and outputs the analog signal potential Vd(3j−2) as a data signal to the (3j−2)-th column data line 14.

The data signal of the potential Vd(3j−2) is applied to the gate node g of the transistor 121 in the pixel portion 110R in the i-th row and the (3j−2)-th column via the data line 14 in the (3j−2)-th column, and the potential Vd(3j−2) is held in the capacitance element 140. Therefore, the transistor 121 causes a current according to a voltage between the gate node and the source node to flow through the OLED 130.

Even when the scanning signal Gwr(i) becomes at the H level and the transistor 122 is turned off, the potential Vd(3j−2) is held in the capacitance element 140, so that a current continues to flow through the OLED 130. Therefore, in the pixel portion 110R in the i-th row and (3j−2)-th column, the OLED 130 continues to emit light at the voltage held in the capacitance element 140, that is, at a brightness corresponding to the gradation level until the period of the one frame (V) has elapsed, the transistor 122 is turned on again, and a voltage of the data signal is applied again.

Although the pixel portion 110R in the i-th row and (3j−2)-th column has been described here, the OLEDs 130 of the pixel portions 110R, 110G, and 110B in the i-th row and the columns other than the (3j−2)-th column also emit light at a luminance indicated by the video data Vdata.

Further, the OLEDs 130 of the pixel portions 110R, 110G, and 110B in the rows other than the i-th row also emit light at the luminance indicated by the video data Vdata as the scanning signals /Gwr(1) to /Gwr(m) sequentially becomes at the L level.

Therefore, in the electro-optical device 10, the OLEDs 130 in all the pixel portions 110R, 110G, and 110B from the first row and the first column to the m-th row and the (3n)-th column emit light at the luminance indicated by the video data Vdata in the period of the one frame (V), and one frame of an image is displayed.

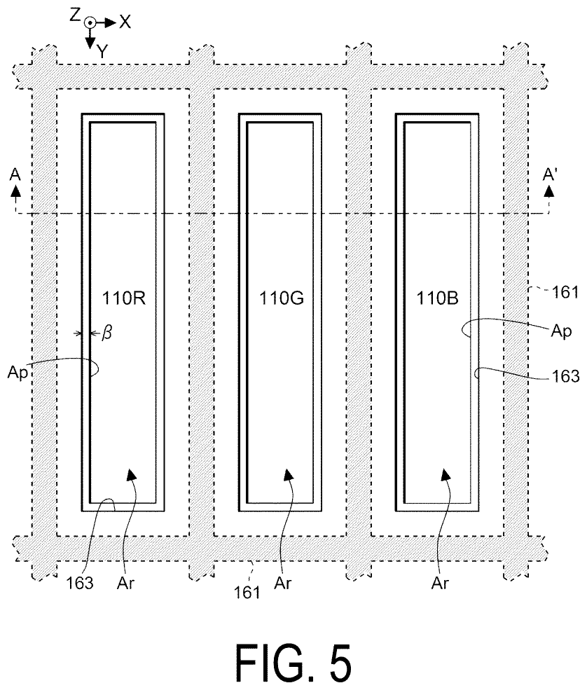

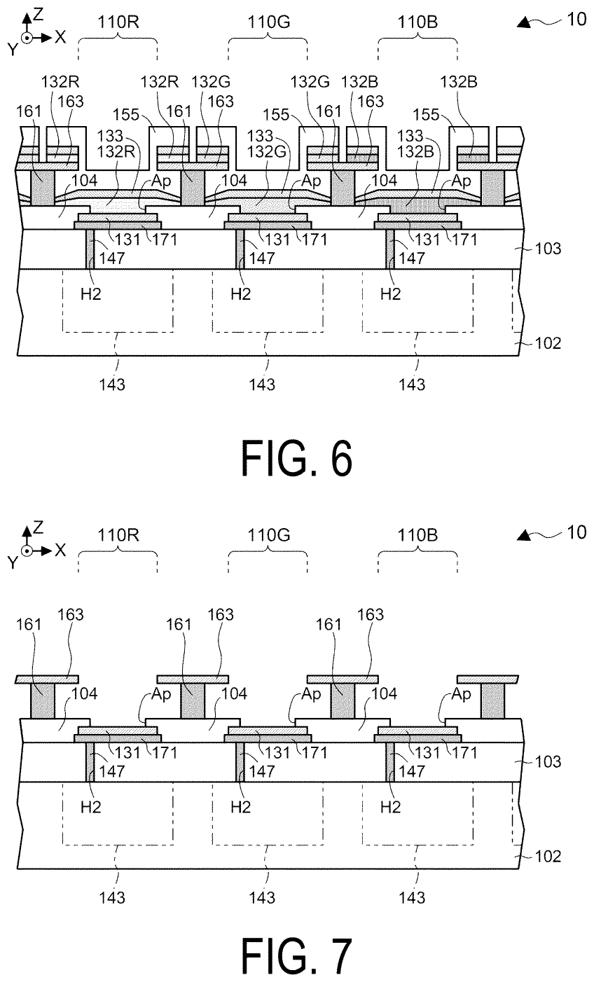

FIG. 5 is a plan view illustrating an example of disposition of the pixel portions 110R, 110G, and 110B in the electro-optical device 10, and FIG. 6 is a cross-sectional view of main parts taken along line A-A′ in FIG. 5.

As illustrated in FIG. 5 and as described above, the pixel portions 110R, 110G, and 110B are arranged side by side in the X direction repeatedly in this order in plan view.

In FIG. 6, the substrate 102 is a semiconductor substrate such as silicon. The substrate 102 is provided with a circuit layer 143. The circuit layer 143 is provided to correspond to the pixel portion 110R, 110G, or 110B, and elements such as the transistors 121 and 122, or various wirings are provided.

An insulating layer 103 is provided on the substrate 102. Contact holes H2 are provided in the insulating layer 103. The contact holes H2 are filled with a coupling member 147 such as tungsten.

A laminated body of a reflective electrode 171 and a pixel electrode 131 is provided for each of the pixel portions 110R, 110G, and 110B.

Specifically, a metal wiring layer having light reflectivity such as Al, an alloy thereof, or Ag is formed at the insulating layer 103 filled with the coupling member 147. After the film formation, the metal wiring layer is in contact with the coupling member 147, and the reflective electrode 171 is provided by patterning of a rectangular shape in plan view.

A transparent conductive layer having optical transparency and conductivity, such as indium tin oxide (ITO) is formed to cover the insulating layer 103 and the reflective electrode 171. After the film formation, the pixel electrode 131 is provided by patterning such that the transparent conductive layer overlaps the reflective electrode 171 and, in plan view, is positioned inside the periphery of the reflective electrode 171. The pixel electrode 131 is light transmittance.

When Al is used for the reflective electrode 171, it is preferable to provide a conductive material such as TiN as a barrier layer with a thickness of about several nm between the reflective electrode 171 and the pixel electrode 131 made of ITO.

Since the reflective electrode 171 comes into contact with the coupling member 147, the pixel electrode 131 is electrically coupled to the drain node of the transistor 121 included in the circuit layer 143 via the reflective electrode 171 and the coupling member 147.

The pixel separation layer 104 having light transmittance and an insulative property is provided to cover the insulating layer 103, the reflective electrode 171, and the pixel electrode 131. Then, an opening region Ar that exposes the pixel electrode 131 by patterning is provided in a pixel separation layer 104. Specifically, in plan view, the opening region Ar has a rectangular shape defined by an opening end Ap, and in cross-sectional view, the opening region Ar is provided to overlap the periphery of the pixel electrode 131, as illustrated in FIG. 6.

After patterning of the pixel separation layer 104, a partition wall 161 and an upper portion 163 are provided.

FIG. 7 is a cross-sectional view illustrating a stage in the manufacturing process of the electro-optical device 10 where a partition wall 161 and an upper portion 163 are provided.

The partition wall 161 and the upper portion 163 are provided, for example, by integrated patterning. Specifically, the partition wall 161 and the upper portion 163 are provided at boundaries between the adjacent pixel portions 110R, 110G, and 110B, as indicated by hatching in FIG. 5, in plan view.

The partition wall 161 and the upper portion 163 are provided in a lattice shape with a portion extending along the X direction and a portion extending along the Y direction in plan view. Therefore, the pixel portions 110R, 110G, and 110B are surrounded by the partition wall 161 and the upper portion 163 in plan view.

The partition wall 161 is made of, for example, a conductive metal wiring layer such as aluminum. The upper portion 163 is made of a conductive metal wiring layer such as titanium, which is made of a material that has a lower etching rate than the partition wall, that is, is less susceptible to etching. The partition wall 161 has a light-shielding property against light emitted by the light-emitting layer 132.

In the integrated etching, since the etching of the partition wall 161 progresses faster than that of the upper portion 163, the upper portion 163 is wider than the partition wall 161 in plan view, and both ends of the upper portion 163 have a so-called overhang structure in which the ends protrude from a side of the partition wall 161 in cross-section view.

The side of the partition wall 161 has a tapered shape in cross-section view as will be described later, that is, a width narrowed in the X direction or Y direction toward an upper surface in the figure, but is not illustrated in the tapered shape in FIGS. 6 and 7 for simplified description. Further, the partition wall 161 extends to the outside of the display region 100 and is electrically coupled to the output terminal of the power supply circuit. Therefore, the partition wall 161 is maintained at the potential Vct generated by the power supply circuit.

Further, the upper portion 163 is made of a conductive metal wiring layer, but may be made of a material having an insulative property.

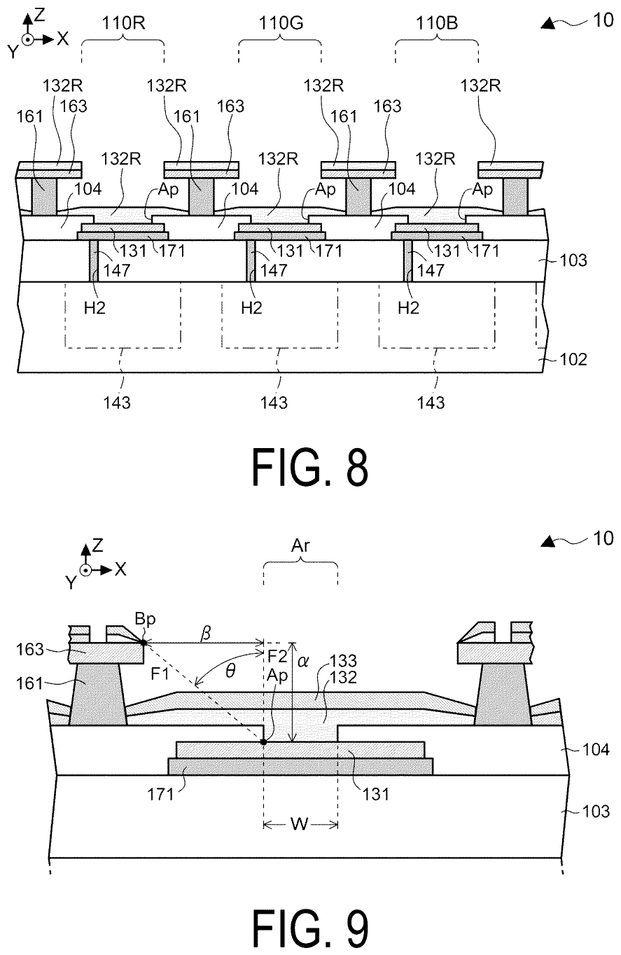

FIG. 8 is a cross-sectional view illustrating a manufacturing process of the electro-optical device 10 immediately after the formation of the light-emitting layer 132R.

The light-emitting layer 132R is deposited from above in the figure. Therefore, the light-emitting layer 132R is formed to cover the opening region Ar of the pixel separation layer 104 in the pixel portion 110R, and is also formed at an upper surface of the upper portion 163.

In other words, the light-emitting layer 132R is formed in the pixel portion 110R to overlap the pixel electrode 131, using the upper portion 163, which has been already provided, as a mask. Therefore, since the light-emitting layer 132R is formed by self-alignment, not by photolithography, an exposure process using an expensive fine metal mask is not required.

The light-emitting layer 132R is also provided in the pixel portions 110G and 110B for different colors at this stage, but is removed by subsequent etching.

After the light-emitting layer 132R is formed, the common electrode 133 is provided by forming a conductive layer having transparency, reflectivity, and conductivity. The common electrode 133 comes into contact with a side wall of the partition wall 161. Therefore, the common electrode 133 is maintained at the potential Vct via the partition wall 161.

In this stage, the light-emitting layer 132R, the common electrode 133, and a sealing layer 155 are provided in an overlapped manner on the pixel electrode 131 in the pixel portions 110G and 110B.

In the pixel portion 110G, the pixel portion 110R is first covered with and protected by photoresist in order to obtain the light-emitting layer 132G for a corresponding correct color. Then, the light-emitting layer 132R, the common electrode 133, and the sealing layer 155 in the pixel portions 110G and 110B are removed by etching to expose the pixel electrode 131.

The G light-emitting layer 132G is formed by self-alignment using the upper portion 163 as a mask, and the common electrode 133 and sealing layer 155 are provided in an overlapped manner, similar to the pixel portion 110R, in the pixel portion 110G.

In this stage, in the pixel portion 110B, the light-emitting layer 132G, the common electrode 133, and the sealing layer 155 are provided in an overlapped manner on the pixel electrode 131.

In the pixel portion 110B, the pixel portion 110G is first covered with and protected by photoresist to obtain the light-emitting layer 132B for a corresponding correct color. Then, the light-emitting layer 132G, the common electrode 133, and the sealing layer 155 in the pixel portion 110B are removed by etching to expose the pixel electrode 131.

In the pixel portion 110B, the B light-emitting layer 132B is formed by self-alignment using the upper portion 163 as a mask, and the common electrode 133 and the sealing layer 155 are provided in an overlapped manner, similar to the pixel portions 110R and 110G.

Accordingly, the configuration as illustrated in FIG. 6 is obtained.

In FIG. 6, the light-emitting layers 132R, 132G, and 132B and the same conductive layer as the common electrode 133 are overlapped on the upper surface of the upper portion 163, but are spaced near the boundaries of the pixel portions 110R, 110G, and 100B. This space is caused by etching for protection of the photoresist.

Then, one or more sealing layers and planarizing layers having an insulative property are provided.

In the electro-optical device 10, even when the light generated in the light-emitting layers 132R, 132G, and 132B travels in the direction opposite to the Z direction, the light is reflected by the reflective electrode 171 and emitted in the Z direction.

The present embodiment adopts a so-called overhang structure in which the upper portion 163 protrudes from the partition wall 161. This overhang structure makes it possible to form the light-emitting layers 132R, 132G, and 132B in a self-aligned manner.

However, on the other hand, when the overhang structure is used, there are problems such as blocking of emitted light and a decrease in aperture ratio.

Since no color distinguishment will be described hereinafter, the pixel portion is denoted by reference number 110 and the light-emitting layer is denoted by reference number 132.

FIG. 9 is an enlarged cross-sectional view illustrating the pixel portion 110 in the electro-optical device 10, and illustrates up to a stage in which the common electrode 133 has been formed. The angle θ is formed between a line F1 that couples the opening end Ap to a tip Bp of the upper surface of the upper portion 163 that protrudes from the partition wall 161 and a line F2 passing through the opening end Ap and directed to a substrate normal direction (Z direction).

A region of the light-emitting layer 132 that emits light when a voltage is applied is a region where the light-emitting layer 132R is sandwiched between the pixel electrode 131 and the common electrode 133, that is, the opening region Ar where the light-emitting layer 132 is in contact with the pixel electrode 131.

Disposition intervals in the X direction of the partition wall 161 is equal to a pitch of the pixel portions 110R, 110G, and 110B. In a micro-display in which the pitch of the pixel portion is about 2 to 3 μm, when a height of the partition wall 161 and the upper portion 163 is about 0.5 to 0.7 μm, when the angle θ becomes large, a width W of the opening region Ar becomes extremely narrow, and the aperture ratio decreases. When the aperture ratio decreases, it is necessary to increase the luminance of the light-emitting layer 132 to ensure brightness. In order to increase the luminance, a current density when the light-emitting layer 132 is driven may be increased. However, when the light-emitting layer 132 is driven with a high current density, the deterioration of the light-emitting layer 132 progresses exponentially. Specifically, when the current density increases four times, a luminance life becomes 1/10 or less. When the luminance life is shortened, not only a screen will become darker, but also the shorter luminance life will have an adverse effect on the quality of products, such as burn-in of the display. The luminance life is a period until the luminance decreases by half when the light-emitting layer 132 is driven under the same conditions.

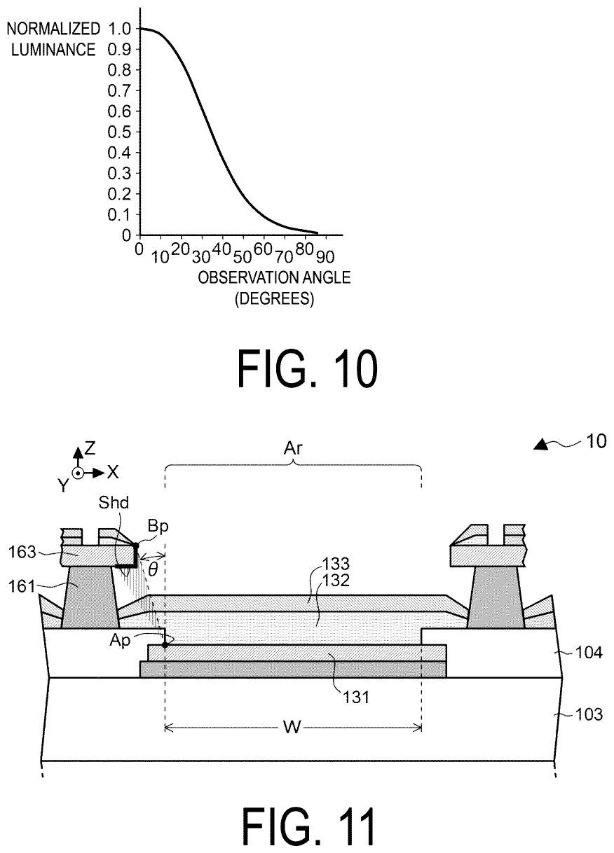

FIG. 10 is a diagram illustrating an example of luminance change with respect to an observation angle in the electro-optical device.

In the figure, the observation angle on a horizontal axis is an angle with respect to the substrate normal direction when the Z direction of the substrate normal direction is set to 0 degrees. Further, in the figure, relative luminance on a vertical axis is a value of relative luminance obtained by normalizing luminance at which the observation angle is 0 degrees by 1.0.

As shown in the figure, the relative luminance decreases as the observation angle increases. An angle at which the luminance is 50% of the luminance at which the observation angle is 0 degrees is in a range of 30 to 40 degrees, and the observation angle at which the luminance is 25% of the luminance at 0 degrees is about 45 degrees. When the observation angle is 45 degrees or more, not only the relative luminance will become low and the display become unsuitable for use, but the decrease in the aperture ratio becomes pronounced as described above.

Therefore, in the micro-display, a limit of the angle θ at which the luminance can be ensured and the decrease in aperture ratio is curbed is 45 degrees.

On the other hand, as the angle θ becomes smaller, the aperture ratio increases. However, when the angle θ is too small, the light emitted from the light-emitting layer 132, particularly the light emitted from the vicinity of the opening end Ap, is shielded by a portion Shd of the upper portion 163 that protrudes from the partition wall 161 as illustrated in FIG. 11, and the use efficiency of the emitted light is degraded. The light shielded by the portion Shd is reflected by the portion Shd, and is subjected to multiple reflections by the side of the partition wall 161, other members having reflectivity, an interface of the insulating layer, or the like, which causes stray light.

About 60% of the total amount of light emitted from the light-emitting layer 132 is emitted in a range of 0 to 20 degrees. Therefore, when the light emitted at an angle θ of 20 degrees is not shielded by the upper portion 163, it is considered that the light emitted from the light-emitting layer 132 can be efficiently extracted to the outside of the electro-optical device 10.

When the angle θ is smaller than 20 degrees, the luminance increases, but the high-luminance light is shielded by the portion Shd to cause multiple reflections, which is not preferable.

Therefore, when the angle @ is less than 45 degrees, it is possible to curb the decrease in the aperture ratio while securing the required luminance. Further, when the angle θ is 20 degrees or more and 40 degrees or less, it is possible to increase the aperture ratio while securing a higher luminance.

For convenience, a distance of a component in the substrate normal direction (Z direction) of the straight line F1 coupling the opening end Ap to the tip Bp is defined as α, that is, a height of the tip Bp with reference to the opening end Ap is defined as α. Also, a distance of s component of the straight line F1 in a direction along the substrate surface is β, that is, a distance from the opening end Ap to the tip Bp when viewed in plan view is β.

The angle θ is expressed as tan⁻¹ (β/α).

In other words, the angle θ being less than 45 degrees can be expressed as

α>β. Also, the angle θ being 20 degrees or more and 40 degrees or less can be expressed as

tan 20°≤(β/α)≤tan 40°.

The common electrode 133 is an example of a “first electrode”, and the pixel electrode 131, or a laminated body of the reflective electrode 171 and the pixel electrode 131, is an example of a “second electrode”.

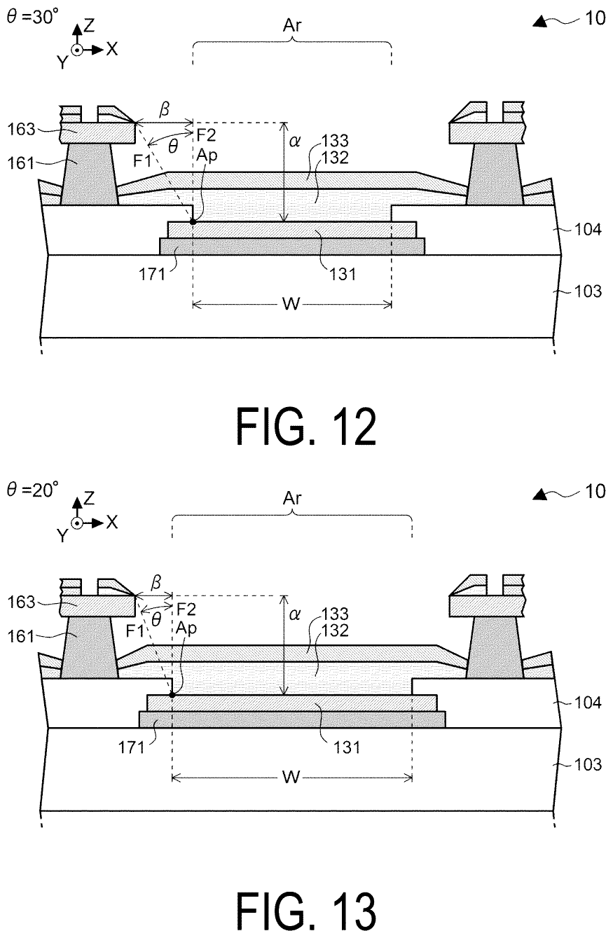

FIG. 12 is a cross-sectional view illustrating main parts of the electro-optical device 10 according to the first embodiment. In the first embodiment, the angle θ is set to 30 degrees.

In this example, since the angle θ is 30 degrees, when a is 0.6 μm, β is about 0.346 μm. When the angle θ is 30 degrees, the width W of the opening region Ar is about 1.5 μm.

About 80% of a total amount of light emitted from the light-emitting layer 132 is emitted in a range of 0 degrees to 30 degrees, but light between 20 degrees and 30 degrees is emitted without being blocked by the portion Shd. Therefore, in the first embodiment, the light emitted from the light-emitting layer 132 can be used efficiently.

FIG. 13 is a cross-sectional view illustrating main parts of the electro-optical device 10 according to a second embodiment. In the second embodiment, the angle θ is set to 20 degrees. In the second embodiment, since the aperture ratio is higher than in the first embodiment, it is possible to secure high luminance. Therefore, the second embodiment is advantageous in terms of the luminance life of the light-emitting layer compared to the first embodiment.

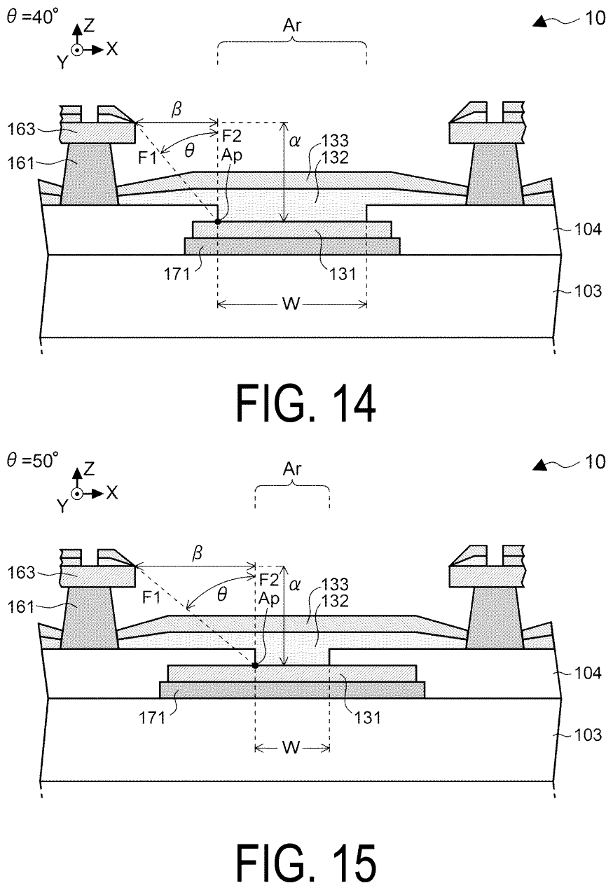

FIG. 14 is a cross-sectional view illustrating main parts of an electro-optical device 10 according to a third embodiment. In the third embodiment, the angle θ is set to 40 degrees. In the third embodiment, the aperture ratio is smaller than in the first embodiment, but the amount of light shielded by portion Shd is reduced, and as a result, a more amount of light can be emitted from the light-emitting layer 132. Specifically, in the third embodiment, it is possible to emit about 90% of the light emitted from the light-emitting layer 132.

FIG. 15 is a cross-sectional view illustrating main parts of an electro-optical device according to a comparative example for comparison with the first to third embodiments. In this comparative example, the angle θ is set to 50 degrees, which is larger than 45 degrees. When the angle θ is 50 degrees, about 95% of the light emitted from the light-emitting layer 132 can be emitted, but the width W of the opening region Ar is about ½ and an area is about ¼ compared to that in the first embodiment. Therefore, in the comparative example, it is necessary for a current density of the light-emitting layer 132 to be about four times that of the first embodiment in order to ensure the same luminance as in the first embodiment. As described above, since the luminance life becomes 1/10 when the current density increases four times, the luminance life becomes shorter, and when the luminance life becomes shorter, not only the screen will become dark due to aging, but also the shorter luminance life will have an adverse effect on the quality of products, such as burn-in of the display.

In the first to third embodiments described above (hereinafter referred to as an “embodiment or the like”), various modifications or applications are possible as follows.

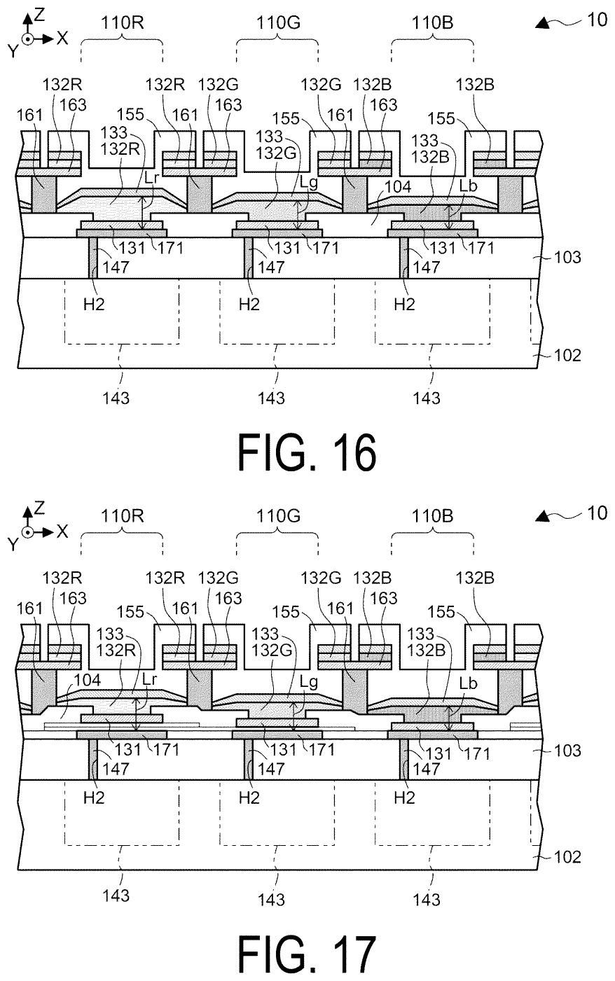

FIG. 16 is a partial cross-sectional view illustrating main parts of the electro-optical device 10 according to a first application example of the embodiment or the like.

In the first application example, pixel portions 110R, 110G, and 100B are provided with an optical resonance structure corresponding to the color. The optical resonance structure refers to a structure in which, when an optical distance between a reflective surface of the common electrode 133 and a reflective surface of the reflective electrode is Lr in the pixel portion 110R, Lg in the pixel portion 110G, and Lb in the pixel portion 110B, the optical distances Lr, Lg, and Lb are set to a distance associated with the wavelengths of each color. Further, a specific example of setting the optical distances Lr, Lg, and Lb to a distance associated with the wavelengths of each color is considered to be a next measure. That is,
a first measure is to make thicknesses of the light-emitting layers 132R, 132G, and 132B different for each color.

A second measure is to make a thickness of the pixel electrode 131 having light transmittance different for each color.

A third measure is to make a sum of the thickness of the pixel electrode 131 and the thickness of the light-emitting layers 132R, 132G, or 132B different for each color. FIG. 16 illustrates the first measure among the measures.

The optical distances Lr, Lg, and Lb have a relationship Lr>Lg>Lb.

In the optical resonance structure, light emitted from the light-emitting layer 132R, 132G, or 132B resonates due to reflection between the reflective electrode 171 and the common electrode 133, and is emitted at a resonance wavelength that has been set to correspond to the color R, G, or B.

Therefore, in the first application example with the optical resonance structure, light having a wavelength corresponding to a color is enhanced and emitted, so that a spectrum is sharpened and intensified, enabling an improvement in both color purity and brightness.

The light-emitting layer 132R, 132G, or 132B has a laminated structure of a hole injection layer, a hole transport layer, a light-emitting functional layer, an electron blocking layer, an electron transport layer, and an electron injection layer, which are not actually shown in the figure. Therefore, it is possible to make a film thickness of the light-emitting layer 132R, 132G, or 132B different for each color by adjusting the thicknesses of the layers for each color.

Strictly speaking, the optical distance is a value obtained by multiplying a distance between the reflective electrode 171 and the common electrode 133 by a refractive index of the pixel electrode 131 and the light-emitting layer, which are media between the reflective electrode 171 and the common electrode 133, but is simply shown as a physical distance in the figure.

Further, in the first application example, the pixel electrode 131 having transparency can be omitted. When the pixel electrode 131 is omitted, the optical distances Lr, Lg, and Lb may be set to distances associated with the wavelengths of the respective colors by using the first measure.

FIG. 17 is a partial cross-sectional view illustrating main parts of an electro-optical device 10 according to a second application example.

The second application example is the same as the first application example in that the pixel portions 110R, 110G, and 100B have optical resonance structures corresponding to the colors. However, the second application example differs from the first application example in that the optical distances Lr, Lg, and Lb are adjusted by a film thickness of an insulating layer provided between the pixel electrode 131 and the reflective electrode 171.

FIG. 17 illustrates an example in which the insulating layer between the pixel electrode 131 and the reflective electrode 171 is not provided in the pixel portion 110B, is one layer in the pixel portion 110G, and includes two layers obtained by adding another insulating layer to the insulating layer, that is the one layer provided in the pixel portion 110G, in the pixel portion 110R.

Since an electric field becomes weaker when the thickness of the light-emitting layer 132 increases, a higher voltage needs to be applied to obtain the same luminance, but in the second application example, the optical distance can be set to Lr>Lg>Lb in a state where the thicknesses of the light-emitting layers 132R, 132G, and 132G are uniform. Therefore, in the second application example, it is not necessary to drive the R light-emitting layer 132R having the longest optical distance with a high voltage in order to increase the color purity and the luminance.

In the embodiment, an opening shape of the opening region Ar in the pixel portions 110R, 110G, and 110B is a rectangular shape, but the present disclosure is not limited thereto. For example, the opening shape may be a polygon such as a hexagon or may be a circle, an ellipse, or the like. Further, an opening area of the opening region Ar may not be uniform in the pixel portions 110R, 110G, and 110B, but may be different for each color. For example, B>G>R for the opening area of the opening region Ar.

The pixel portions 110R, 110G, and 110B may be aligned in the X direction or may be aligned in the Y direction. Further, the pixel portions 110R and 110B may be arranged in the same columns, and the pixel portion 110G may be arranged in a column adjacent to the column of the pixel portions 110R and 110B.

In the description of the embodiment or the like, the light-emitting layers 132R, 132G, and 132B are formed in this order, but the order of layer formation is not limited thereto.

Next, an electronic apparatus to which the electro-optical device 10 according to the embodiment is applied will be described. The electro-optical device 10 is suitable for application of a small pixel size and high definition display. Consequently, a head-mounted display will be described as an example of the electronic apparatus.

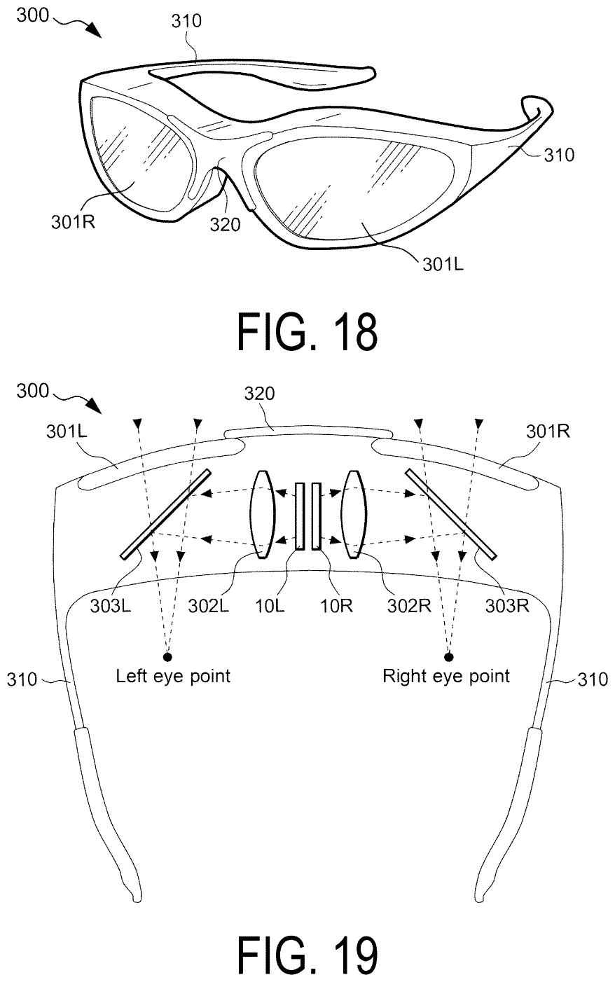

FIG. 18 is a diagram illustrating an appearance of a head-mounted display, and FIG. 19 is a diagram illustrating an optical configuration thereof.

First, as illustrated in FIG. 18, the head-mounted display 300 includes temples 310, a bridge 320, and lenses 301L and 301R in appearance, similar to ordinary glasses. Further, the head-mounted display 300 includes an electro-optical device 10L for a left eye and an electro-optical device 10R for a right eye near the bridge 320 and behind the lenses 301L and 301R (below in the figure), as illustrated in FIG. 19.

An image display surface of the electro-optical device 10L is disposed to the left in FIG. 19. Accordingly, an image displayed by the electro-optical device 10L is output in a 9 o'clock direction in the figure via the optical lens 302L. A half mirror 303L reflects an image displayed by the electro-optical device 10L in the 6 o'clock direction, and transmits light incident from a 12 o'clock direction. An image display surface of the electro-optical device 10R is disposed to the right opposite to the electro-optical device 10L. Accordingly, an image displayed by the electro-optical device 10R is emitted in a 3 o'clock direction in the figure through an optical lens 302R. A half mirror 303R reflects an image displayed by the electro-optical device 10R in the 6 o'clock direction, and transmits light incident from the 12 o'clock direction.

In this configuration, a wearer of the head-mounted display 300 can observe the display images of the electro-optical devices 10L and 10R in a see-through state in which the display images are superimposed on an outside world.

Furthermore, in the head-mounted display 300, an image for the left eye is displayed by the electro-optical device 10L, and an image for the right eye is displayed by the electro-optical device 10R in the images for both eyes involving parallax, so that it enables the wearer to sense the displayed image as having depth or stereoscopic effect.

The electronic apparatus including the electro-optical device 10 can be applied to an electronic viewfinder in a video camera or an interchangeable lens digital camera, a smart watch, a display unit of a wearable device, a light bulb in a projection projector, and the like, in addition to the head-mounted display 300.

From the aspects illustrated above, the following aspects can be ascertained, for example. Hereinafter, for ease of understanding of each aspect, the reference signs in the drawings are conveniently written in parentheses, but this is not intended to limit the aspects to those shown.

An electro-optical device (10) according to one embodiment 1 includes a substrate (102), a first electrode (133), a second electrode (131, 171) provided between the substrate (102) and the first electrode (133), a pixel separation layer (104) having an insulative property and covering the periphery of the second electrode (131, 171), and opening in an opening region (Ar) overlapping the second electrode (131, 171) in plan view, a light-emitting layer (132) provided between the first electrode (133) and the second electrode (131, 171) and being in contact with the second electrode (131, 171) in the opening region (Ar), a partition wall (161) having a light-shielding property against light emitted by the light-emitting layer (132) and surrounding the first electrode (133), the light-emitting layer (132), and the second electrode (131, 171) in plan view, and an upper portion (163) provided so as to protrude from the partition wall in cross-sectional view on the upper surface of the partition wall (161) and having a light-shielding property against light emitted by the light-emitting layer (132), wherein, when a distance of a normal component to the substrate (102) of a shortest straight line coupling a tip of the upper portion (163) to an opening end (Ap) of the opening region (Ar) in cross-sectional view is defined as x, and a distance of a component of the straight line along a surface of the substrate (102) is β, there is a relationship of α>β.

According to the electro-optical device of aspect 1, when α>β, that is, the angle θ is greater than 45 degrees, it is possible to ensure the luminance and to curb the decrease in the aperture ratio due to the narrowing of the opening region.

In the electro-optical device (10) according to specific aspect 2 of aspect 1, a and B have a relationship of tan 20°≤(β/α)≤tan 40°.

According to aspect 2, it is possible to curb the decrease in aperture ratio while ensuring high luminance, and to increase the use efficiency of the emitted light.

In the electro-optical device (10) according to another specific aspect 3 of aspect 1, the second electrode (131, 171) is a laminated body of a reflective electrode (171) and a pixel electrode (131) having reflectivity when viewed from the substrate (102), and the first electrode (133) has light transmittance and reflectivity.

In the electro-optical device (10) according to another specific aspect 4 of aspect 1, the second electrode (171) is a reflective electrode (171) having reflectivity, and the first electrode (133) has light transmittance and reflectivity.

The electro-optical device (10) according to another specific alternative aspect 5 of aspect 1 includes a sealing layer (155) having an insulative property and light transmittance and covering the first electrode (133).

In the electro-optical device (10) according to a specific alternative aspect 6 of aspect 1, the partition wall (161) has conductivity, and the first electrode (133) is in contact with the partition wall (161).

An electronic apparatus (300) according to aspect 8 includes the electro-optical device (10) according to any one of aspects 1 to 6.

What is claimed is:

1. An electro-optical device comprising:
a substrate;
a first electrode;
a second electrode provided between the substrate and the first electrode;
a pixel separation layer having an insulative property, covering a periphery of the second electrode, and opening in an opening region overlapping the second electrode in plan view;
a light-emitting layer provided between the first electrode and the second electrode and being in contact with the second electrode in the opening region;
a partition wall having a light-shielding property against light emitted by the light-emitting layer and surrounding the first electrode, the light-emitting layer, and the second electrode in plan view; and
an upper portion provided so as to protrude from the partition wall in cross-sectional view on an upper surface of the partition wall, and having a light-shielding property against light emitted by the light-emitting layer, wherein
when a distance of a normal component to the substrate of a shortest straight line coupling a tip of the upper portion to an opening end of the opening region in cross-sectional view is defined as a, and
a distance of a component of the straight line along a surface of the substrate is defined as β,
there is a relationship of α>β.

2. The electro-optical device according to claim 1,
wherein α and β have a relationship of tan 20°≤(β/α)≤tan 40°.

3. The electro-optical device according to claim 1, wherein
the second electrode is a laminated body of a reflective electrode and a pixel electrode having reflectivity when viewed from the substrate, and
the first electrode has light transmittance and reflectivity.

4. The electro-optical device according to claim 1, wherein
the second electrode is a reflective electrode having reflectivity, and
the first electrode has light transmittance and reflectivity.

5. The electro-optical device according to claim 1, comprising
a sealing layer having an insulative property and light transmittance and covering the first electrode.

6. The electro-optical device according to claim 1, wherein
the partition wall has conductivity, and
the first electrode is in contact with the partition wall.

7. An electronic apparatus comprising the electro-optical device according to claim 1.
